(19) United States
(12) Patent Application Publication
(10) Pub. No.: US 2026/0208317 A1
(43) Pub. Date: Jul. 23, 2026

(54) SUBSTRATE POLISHING SYSTEM

(71) Applicant: Samsung Electronics Co., Ltd., Suwon-si (KR)

(72) Inventors: Wonguk Seo, Suwon-si (KR); Boun Yoon, Suwon-si (KR); Jinhan Choi, Suwon-si (KR); Kuihyun Yoon, Suwon-si (KR); Sungho Jang, Suwon-si (KR); Myungho Jung, Suwon-si (KR)

(21) Appl. No.: 19/451,439

(22) Filed: Jan. 16, 2026

(30) Foreign Application Priority Data
Jan. 21, 2025 (KR) 10-2025-0008889

(51) Int. Cl. B24B 37/34; B08B 3/02; B24B 7/22; B24B 37/015; B24B 41/047; B24B 49/04

(52) U.S. Cl. CPC B24B 37/345; B08B 3/02; B24B 7/228; B24B 37/015; B24B 41/047; B24B 49/04

(57) ABSTRACT

A substrate polishing system includes an index module having a load port configured to support wafer carriers, each of the wafer carriers configured to support a plurality of wafers, and an index chamber configured to transfer wafers to and from the wafer carriers; a transfer chamber extending in a first direction from a first side of the index module; and a plurality of polishing units sequentially arranged in the first direction along a first side of the transfer chamber. Each polishing unit of the plurality of polishing units includes vertically stacked polishing chambers stacked in multiple stages, and the vertically stacked polishing chambers include a rough polishing chamber and a fine polishing chamber.

### PRIORITY STATEMENT

This application claims priority under 35 U.S.C. § 119 to Korean Patent Application No. 10-2025-0008889, filed on January 21, 2025, in the Korean Intellectual Property Office (KIPO), the contents of which are herein incorporated by reference in their entirety.

### BACKGROUND

### Field

Example embodiments relate to a substrate polishing system. More particularly, example embodiments relate to a substrate polishing system for sequentially polishing a plurality of wafers and a substrate polishing method using the same.

### Description of the Related Art

In general, a chemical mechanical polishing (CMP) process may be performed to reduce a thickness of a wafer or partially remove an upper surface of a target layer on the wafer. The chemical mechanical polishing process may typically be performed in the following order: wafer loading, wafer aligning, rough polishing, fine polishing, cleaning, wafer unloading. The rough polishing step and the fine polishing step may be sequentially performed using two identical polishing apparatuses that are arranged on a plane, and then the cleaning step may be sequentially performed using a plurality of cleaning apparatuses. When a consumable of any one of the polishing apparatuses and the cleaning apparatuses is replaced or breaks down, the entire process may be stopped, which causes a problem in that the process efficiency is reduced. In addition, there is a limit to space (footprint) efficiency due to the horizontal layout, and since the rough polishing process and the fine polishing process are performed using the same polishing apparatuses, there is a problem in that the efficiency is reduced in terms of facility operation and cost.

### SUMMARY

Example embodiments provide a substrate polishing system with a layout that maximizes the integration of equipment units and enables efficient equipment operation.

According to example embodiments, a substrate polishing system includes an index module having a load port configured to support wafer carriers, each of the wafer carriers configured to support a plurality of wafers, and an index chamber configured to transfer wafers to and from the wafer carriers; a transfer chamber extending in a first direction from a first side of the index module; and a plurality of polishing units sequentially arranged along the first direction in a first side of the transfer chamber. Each polishing unit of the plurality of polishing units includes vertically stacked polishing chambers stacked in multiple stages, and the vertically stacked polishing chambers include a rough polishing chamber and a fine polishing chamber.

According to example embodiments, a substrate polishing system includes an index module having a load port configured to support wafer carriers, each of the wafer carriers configured to support a plurality of wafers, and an index chamber configured to load and unload the plurality of wafers; a transfer chamber extending in a first direction from a first side of the index module and having a transfer robot that is movable along the first direction; a plurality of polishing units sequentially arranged in the first direction along a first side of the transfer chamber; and a plurality of cleaning units sequentially arranged in the first direction along a second side of the transfer chamber opposite to the first side. Each polishing unit of the plurality of polishing units includes vertically stacked polishing chambers stacked in multiple stages, and the vertically stacked polishing chambers include a rough polishing chamber and a fine polishing chamber. Each cleaning unit of the plurality of cleaning units includes vertically stacked cleaning chambers stacked in multiple stages.

According to example embodiments, a substrate polishing system includes a transfer chamber extending in a first direction, the transfer chamber having a first end configured to receive wafers; a plurality of polishing units arranged sequentially in the first direction along a first side of the transfer chamber; a plurality of cleaning units arranged sequentially in the first direction along a second side of the transfer chamber opposite to the first side; and a transfer robot within the transfer chamber movable in the first direction and along a vertical transfer path to transfer the wafers between the first end of the transfer chamber, the plurality of polishing units, and the plurality of cleaning units. Each polishing unit of the plurality of polishing units includes vertically stacked polishing chambers that are stacked in multiple stages, and the vertically stacked polishing chambers include a rough polishing chamber and a fine polishing chamber that is stacked on the rough polishing chamber. Each cleaning unit of the plurality of cleaning units includes vertically stacked cleaning chambers that are stacked in multiple stages.

According to example embodiments, a plurality of polishing units and a plurality of cleaning units may be arranged in parallel with a transfer chamber interposed therebetween, and each of the polishing units may include one or more polishing chambers and one or more fine polishing chambers that are stacked in a vertical direction, and each of the cleaning units may include cleaning chambers of the same or different types that are stacked in the vertical direction.

Accordingly, the wafer transfer path between the polishing units and the cleaning units may be parallelized to improve the facility efficiency. Each of the polishing units may have a compact size and improve the precision of the polishing process. Since the number of the rough polishing chambers is greater than the number of the fine polishing chambers, the process time balance may be improved by considering each polishing process time. Further, since the rough polishing chamber and the fine polishing chamber of each polishing unit are arranged in a vertical structure, the integration of the unit may be improved, thereby improving the production per hour (UPEH).

### BRIEF DESCRIPTION OF THE DRAWINGS

Example embodiments will be more clearly understood from the following detailed description taken in conjunction with the accompanying drawings. FIGS. 1 to 11C represent non-limiting, example embodiments as described herein.

FIG. 1 is a plan view illustrating a substrate polishing system in accordance with example embodiments.

FIG. 2 is a cross-sectional view taken along the line A1-A1’ in FIG. 1.

FIG. 3 is a cross-sectional view taken along the line A2-A2’ in FIG. 1.

FIG. 4 is a cross-sectional view taken along the line A3-A3’ in FIG. 1.

FIG. 5 is a cross-sectional view illustrating a rough polishing apparatus in accordance with example embodiments.

FIG. 6 is a plan view illustrating the rough polishing apparatus of FIG. 5.

FIG. 7 is a cross-sectional view illustrating a fine polishing apparatus in accordance with example embodiments.

FIG. 8 is a plan view illustrating the fine polishing apparatus of FIG. 7.

FIG. 9 is a cross-sectional view illustrating a gas spray nozzle of the fine polishing apparatus of FIG. 7.

FIG. 10 is a flow chart illustrating a substrate processing method in accordance with example embodiments.

FIGS. 11A, 11B, and 11C are cross-sectional views illustrating a target layer on a substrate on which the substrate processing method of FIG. 10 is performed.

### DETAILED DESCRIPTION OF EXAMPLE EMBODIMENTS

Hereinafter, the present disclosure will be explained in detail with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

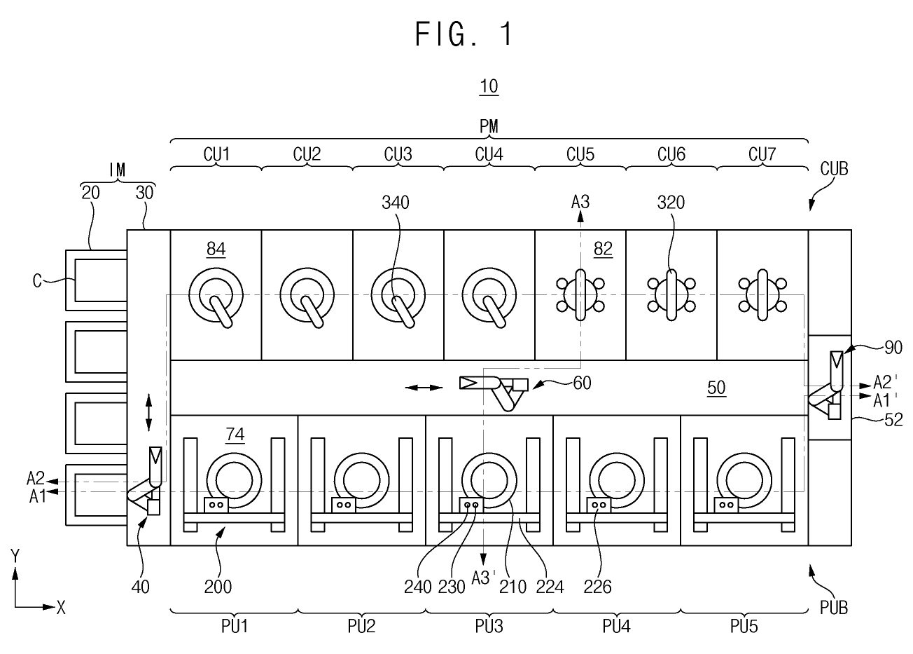

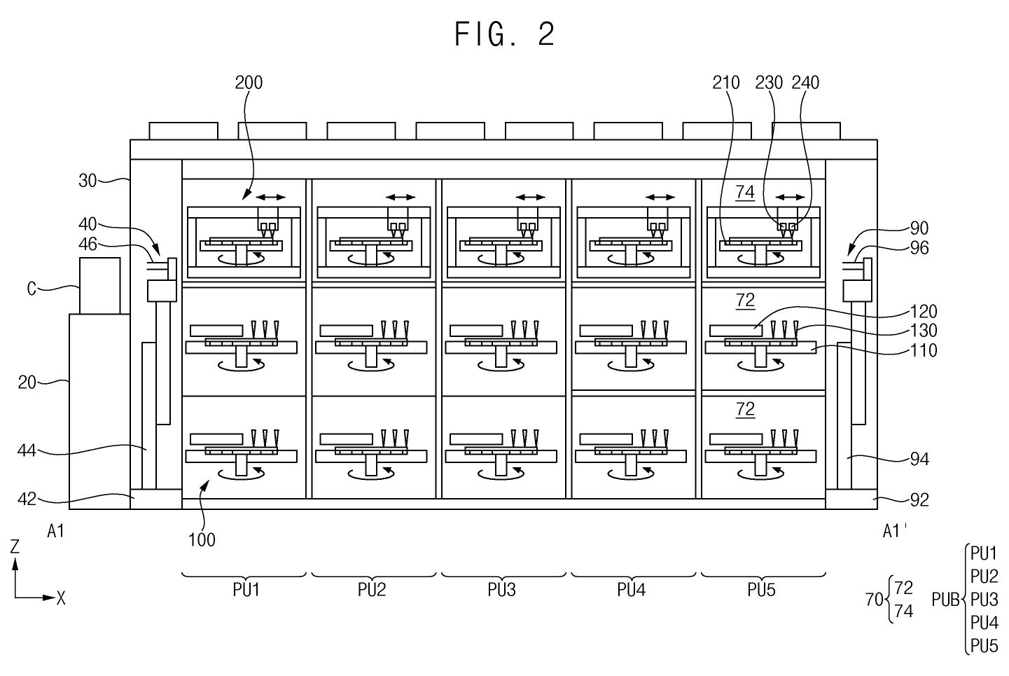

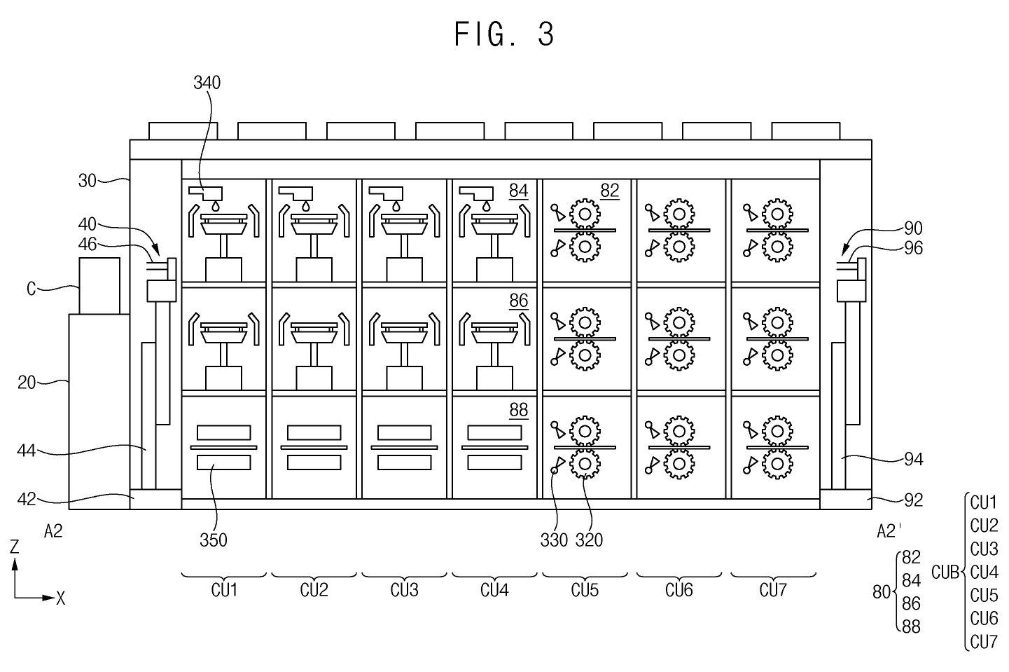

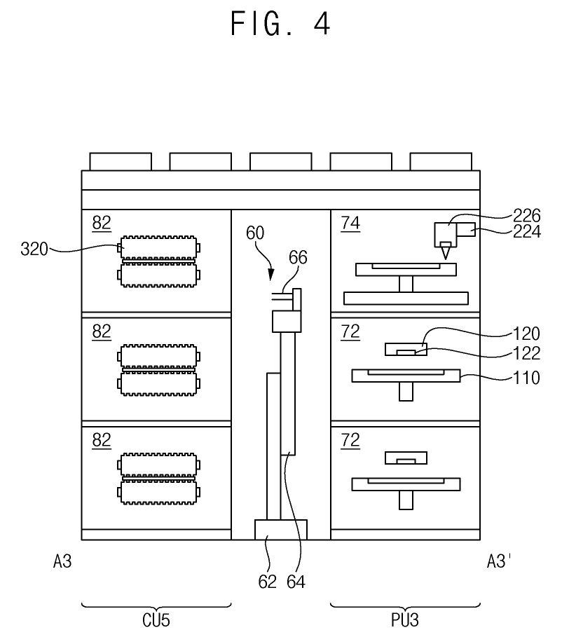

FIG. 1 is a plan view illustrating a substrate polishing system in accordance with example embodiments. FIG. 2 is a cross-sectional view taken along the line A1-A1’ in FIG. 1. FIG. 3 is a cross-sectional view taken along the line A2-A2’ in FIG. 1. FIG. 4 is a cross-sectional view taken along the line A3-A3’ in FIG. 1.

Referring to FIGS. 1 to 4, a substrate polishing system 10 may include an index module IM configured to load and unload wafers W, and a process module PM arranged at one side of the index module IM and configured to sequentially perform a polishing process and a cleaning process on the wafers. The index module IM and the process module PM may be arranged along a first direction (X direction). The index module IM may include a load port 20 and an index chamber 30. The process module PM may include a transfer chamber 50, a polishing unit block PUB, and a cleaning unit block CUB.

In example embodiments, the substrate polishing system 10 may perform a semiconductor process such as a polishing process and a cleaning process, on a substrate such as the wafer. For example, in a plurality of polishing units PU, a rough polishing process and a fine polishing process may be sequentially performed on substrates, and in a plurality of polishing units PU, various cleaning processes for cleaning substrates may be performed.

As illustrated in FIG. 1, the load port 20 may include a support plate for supporting a wafer carrier C (FOUP; front opening unified pod) in which a plurality of wafers W are received. The load port 20 is a portion of the index module IM where a substrate is loaded or unloaded, and a plurality of support plates may be arranged in the load port 20 along a second direction (Y direction) perpendicular to the first direction.

The index chamber 30 may include an indexer robot 40 arranged within a rectangular frame. The indexer robot 40 may be movable along an index rail extending in the second direction (Y direction) within the frame. The indexer robot 40 may transfer the wafer between the wafer carrier C on the support plate and the process module. The indexer robot 40 may include a base 42, a vertical guide 44, and a robot hand 46. The base 42 may be installed to be movable in the second direction (Y direction) along the index rail, the vertical guide 44 may be extended to be able to ascend and descend in a vertical direction (Z direction) on the base 42, and the robot hand 46 may be installed to be movable in the vertical direction along the vertical guide 44.

In example embodiments, the transfer chamber 50 may extend in the first direction (X direction) from the index chamber 30. The polishing unit block PUB may be arranged in a first side of the transfer chamber 50, and the cleaning unit block CUB may be arranged in a second side of the transfer chamber 50 opposite to the first side. The polishing unit block PUB may include a plurality of polishing units PU sequentially arranged in the first direction (X direction) along the first side of the transfer chamber 50. The cleaning unit block CUB may include a plurality of cleaning units CU sequentially arranged in the first direction (X direction) along the second side of the transfer chamber 50. The plurality of polishing units PU and the plurality of cleaning units CU may be sequentially arranged in the first direction (X direction) in parallel with each other with the transfer chamber 50 interposed therebetween.

Each of the plurality of polishing units PU may include a plurality of polishing chambers 70 that are stacked in multiple stages in the vertical direction (Z direction). The polishing chambers 70 that are stacked in the vertical direction (Z direction) may include at least one rough polishing chamber 72 and at least one fine polishing chamber 74. A rough polishing process may be performed in the rough polishing chamber 72, and a fine polishing process may be performed in the fine polishing chamber 74. The at least one fine polishing chamber 74 may be stacked on the at least one rough polishing chamber 72. The number of the rough polishing chambers 72 of each polishing unit PU may be greater than the number of the fine polishing chambers 74.

Each of the plurality of cleaning units CU may include a plurality of cleaning chambers 80 that are stacked in multiple stages in the vertical direction (Z direction). The cleaning chambers 80 that are stacked in multiple stages in the vertical direction (Z direction) may include at least one of a first cleaning chamber 82 of a brush type using a brush, a second cleaning chamber 84 of a nozzle type using a cleaning nozzle, a buffing chamber 86, and a drying chamber 88.

As illustrated in FIGS. 2 to 4, first, second, third, fourth, and fifth polishing units PU1, PU2, PU3, PU4, PU5 may be sequentially arranged in the first direction (X direction). Each of the first, second, third, fourth, and fifth polishing units PU1, PU2, PU3, PU4, PU5 may include a plurality of polishing chambers 70 that are stacked in multiple stages. The polishing chambers 70 stacked in the vertical direction (Z direction) may include two rough polishing chambers 72 and one fine polishing chamber 74 that are sequentially stacked on each other. One fine polishing chamber 74 may be stacked on two rough polishing chambers 72.

It will be understood that the number of the plurality of polishing units, the number and arrangement of the rough polishing chambers and the fine polishing chambers, etc. are not limited thereto.

First, second, third, fourth, fifth, sixth and seventh cleaning units CU1, CU2, CU3, CU4, CU5, CU6, CU7 may be sequentially arranged in the first direction (X direction). Each of the first, second, third, fourth, fifth, sixth and seventh cleaning units CU1, CU2, CU3, CU4, CU5, CU6, CU7 may include a plurality of cleaning chambers 80 that are stacked in multiple stages. Each of the first, second and third cleaning units CU1, CU2, CU3 may include three first cleaning chambers 82 that are stacked with each other in the vertical direction (Z direction). Each of the fourth, fifth, sixth and seventh cleaning units CU4, CU5, CU6, CU7 may include a second cleaning chamber 84, a buffing chamber 88 and a drying chamber 86 that are stacked on each other. The drying chamber 86 may be stacked on the buffing chamber 88, and the second cleaning chamber 84 may be stacked on the drying chamber 86. The first cleaning chambers 82 may include a brush 320. The second cleaning chambers 84 may include a cleaning nozzle (e.g., spray nozzle 330). The drying chamber 86 may include a spin drying apparatus for rotating the substrate at a high speed to remove a droplet attached to the substrate. The buffing chamber 88 may include a buffing pad 350.

It will be understood that the number of the plurality of cleaning units, the number and arrangement of the first cleaning chambers, the second cleaning chambers, the drying chambers, and the buffing chambers, etc. are not limited thereto.

The transfer chamber 50 for transferring the wafer may be provided between the plurality of polishing units PU and the plurality of cleaning units CU. A transfer robot 60 may move along a transfer rail extending along the first direction (X direction) and transfer the wafer. The transfer robot 60 may include a base 62, a vertical guide 64, and a robot hand 66. The base 62 may be installed to be movable along the transfer rail in the first direction (X direction), the vertical guide 64 may be extended to be able to ascend and descend in the vertical direction (Z direction) on the base 62, and the robot hand 66 may be installed to be able to move along a vertical guide 75 in the vertical direction.

The transfer robot 60 may transfer the wafer from the index chamber 30 to the rough polishing chamber 72 of the polishing unit PU. The transfer robot 60 may transfer the wafer on which the rough polishing process has been performed in the rough polishing chamber 72, to the fine polishing chamber 74. The transfer robot 60 may sequentially transfer the wafer on which the fine polishing process has been performed in the fine polishing chamber 74, to the cleaning chambers 80 of the cleaning unit CU. The transfer robot 60 may sequentially pass through the first cleaning chamber 82, the second cleaning chamber 84, the buffing chamber 88, and the drying chamber 86 among the cleaning chambers 80 according to the cleaning recipe, and then transfer the wafer on which the cleaning process has been performed, back to the index chamber 30.

In addition, the substrate polishing system 10 may further include inspection chambers configured to inspect stains and particles on the substrate on which the polishing process and the cleaning process are completed. The inspection chambers may be provided in one side of the polishing unit block PUB or one side of the cleaning unit block CUB. An inspection transfer robot 90 may transfer the wafer on which the cleaning process is performed to the inspection chamber to perform the inspection process. The wafer on which the inspection process is performed may be transferred back to the index module IM by the inspection transfer robot 90 and the transfer robot 60.

As described above, the polishing units PU and the cleaning units CU may be arranged in parallel, and each of the polishing units PU may include at least one rough polishing chamber 72 and at least one fine polishing chamber 74 that are stacked in the vertical direction (Z direction), and each of the cleaning units CU may include cleaning chambers 80 of the same or different types that are stacked in the vertical direction (Z direction).

Accordingly, the wafer transfer path between the polishing units PU and the cleaning units CU may be parallelized to improve the facility efficiency.

In addition, the rough polishing chamber 72 of the polishing unit PU may include a first polishing apparatus for efficiently performing a rough polishing process during a first process time, and the fine polishing chamber 74 of the polishing unit PU may include a second polishing apparatus for efficiently performing a fine polishing process during a second process time shorter than the first process time. Since the first polishing apparatus and the second polishing apparatus perform different functions, they may have a compact size and improve the precision of the polishing process. Since the number of the rough polishing chambers 72 is greater than the number of the fine polishing chambers 74, the process time balance may be improved by considering each polishing process time.

Furthermore, since the rough polishing chamber 72 and the fine polishing chamber 74 of each polishing unit are arranged in a vertical structure, the integration of the unit may be improved, thereby improving the production per hour (UPEH).

The arrangement of the load port, the index module, and the process module, the arrangement and number of the polishing units and the cleaning units are illustrated as examples, and it will be understood that example embodiments are not limited thereto.

Hereinafter, the first polishing apparatus of the rough polishing chamber will be described in detail.

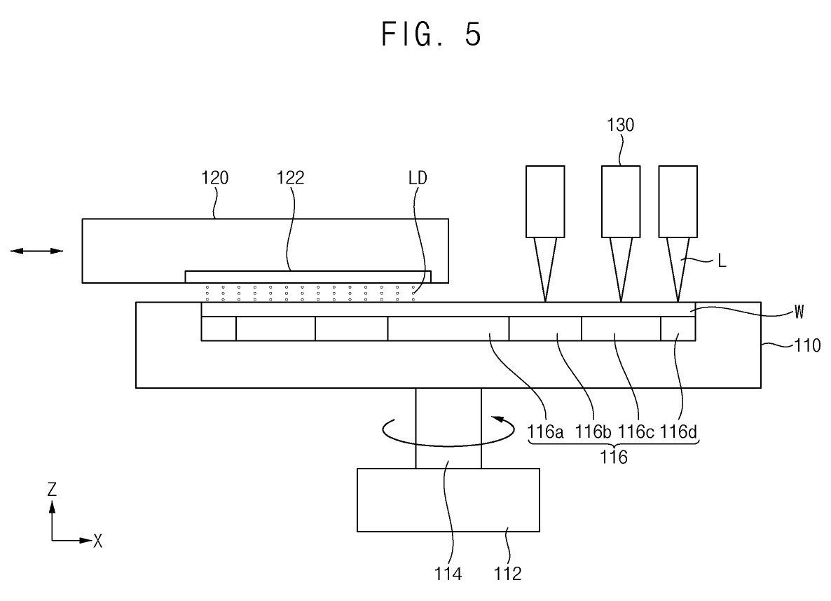

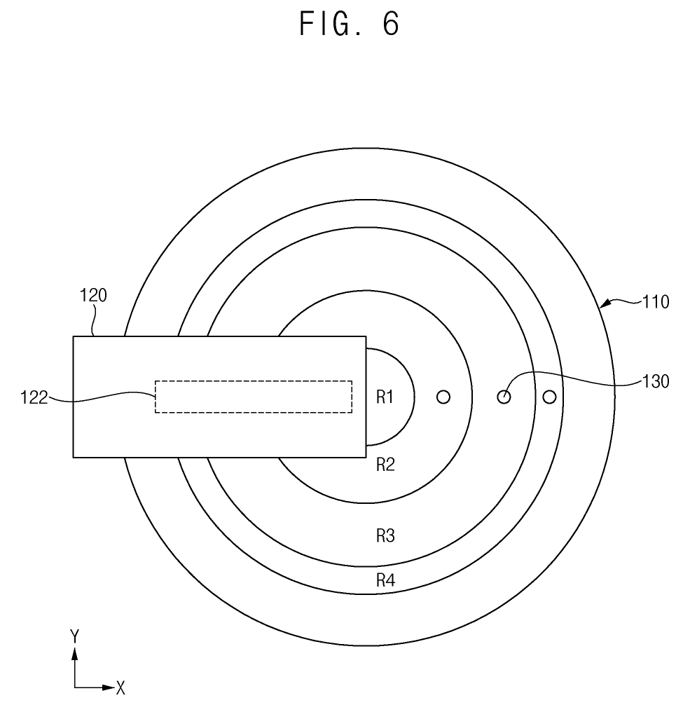

FIG. 5 is a cross-sectional view illustrating a rough polishing apparatus in accordance with example embodiments. FIG. 6 is a plan view illustrating the rough polishing apparatus of FIG. 5.

Referring to FIGS. 5 and 6, a rough polishing apparatus 100 may be provided in the rough polishing chamber 72 of FIG. 2 and may perform a polishing process by spraying high-speed droplets without a polishing pad or abrasive.

In example embodiments, the rough polishing apparatus 100 may include a first substrate stage 110 configured to support a wafer W, a fluid injection portion 120 above the first substrate stage 110 and configured to inject a high-pressure fluid (LD), i.e., a droplet, onto a surface of the wafer, and at least one thickness measurement sensor 130 above the first substrate stage 110 and positioned to measure a thickness of a target layer on the surface of the wafer. For example, the thickness measurement sensor 130 may be positioned above or to the side of the wafer.

As illustrated in FIGS. 5 and 6, the first substrate stage 110 may be supported by a rotation shaft 114 and may rotate the wafer W at a desired rotation speed. While the first substrate stage 110 rotates, the wafer W may be adsorbed and fixedly supported on the first substrate stage 110.

The first substrate stage 110 may include a plurality of adsorption portions R1, R2, R3, R4 sequentially arranged in a radial direction from a center thereof, and temperature controllers 116a, 116b, 116c, 116d configured to control the temperature of each of the plurality of adsorption portions.

For example, suction holes may be formed in upper surfaces of the plurality of adsorption portions R1, R2, R3, R4. The wafer W may be vacuum-absorbed by the suction holes formed in an upper surface of the first substrate stage 110. The suction holes of the first to fourth adsorption portions R1, R2, R3, R4 may be individually connected to a vacuum pump (not illustrated) through pipes. Vacuum pressure may be supplied to the suction holes individually or in groups. In this embodiment, four adsorption portions may be provided, but is not limited thereto, and the first substrate stage may have a plurality of adsorption portions, such as three, five, or six. Alternatively, the wafer may be absorbed using an electrostatic force, such as an electrostatic chuck.

The temperature controllers 116a, 116b, 116c, 116d may be provided in the first to fourth adsorption portions R1, R2, R3, R4 to control the temperature of each of the adsorption portions. For example, the temperature controllers 116a, 116b, 116c, 116d may include heating elements such as a heating element or a resistance heating wire. In addition, the temperature controllers 116a, 116b, 116c, 116d may include refrigerant circulation lines for circulating refrigerant. The temperature controllers 116a, 116b, 116c, 116d may be independently controlled to perform local heating or cooling treatment on the wafer. Additionally, the temperature controllers 116a, 116b, 116c, 116d may include temperature sensors to measure the temperature of each of the adsorption portions R1, R2, R3, R4 and provide a feedback signal to adjust the amount of heat produced by a heating element or quantity of cooling.

In example embodiments, the fluid injection portion 120 may include a fluid discharge head 122 having ejection holes spaced apart from each other along one direction and each ejecting droplets (LD). The fluid injection portion 120 may be installed to be movable in the radial direction (e.g., X direction) of the first substrate stage 110. The discharge pressure of the ejection holes may be adjusted to control the ejection speeds of the droplets.

A plurality of thickness measurement sensors 130 may be spaced apart from each other in the radial direction (e.g., X direction) of the first substrate stage 110 above the first substrate stage 110. The thickness measurement sensors 130 may irradiate light L onto the wafer surface and detect a reflected light to measure a change in distance from the wafer surface. In addition, the thickness measurement sensors 130 may detect polarization to measure a thickness of the target layer on the wafer.

In example embodiments, a rough polishing process may be performed by spraying high-speed droplets without a polishing pad or an abrasive, so that maintenance of consumables is not required, there are no defects caused by the abrasive, and a conditioner may be eliminated. In addition, by directly measuring the wafer surface, thickness measurement resolution may be improved to a level of 0.1 nm. Further, the polishing efficiency may be improved by reducing the temperature deviation through local heating and cooling treatment of the wafer through the temperature controllers.

In this embodiment, the rough polishing apparatus 100 may include the fluid discharge head 122 for performing a polishing process by spraying high-speed droplets, but is not limited thereto. For example, the rough polishing apparatus may perform a polishing process by using friction with a polishing pad together with slurry, like a conventional polishing apparatus, or by spraying a fluid gas such as plasma gas.

Hereinafter, the second polishing apparatus of the fine polishing chamber will be described in detail.

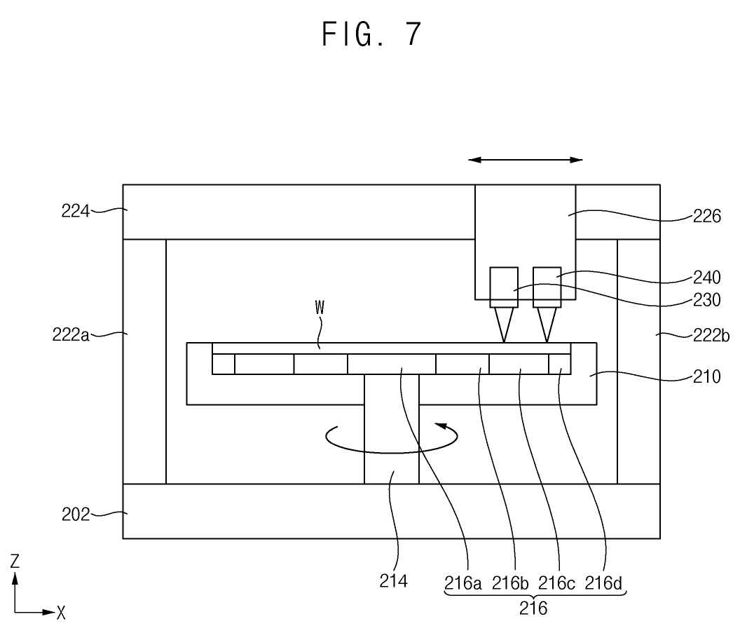

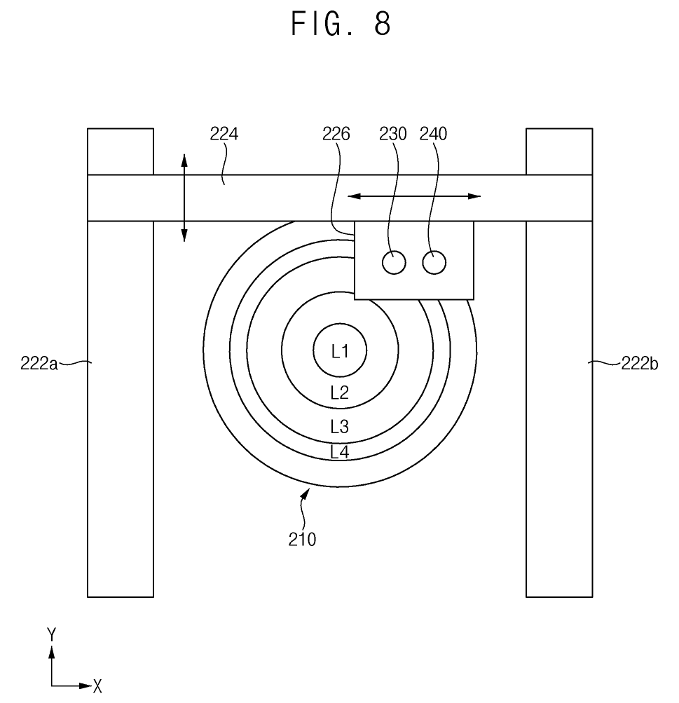

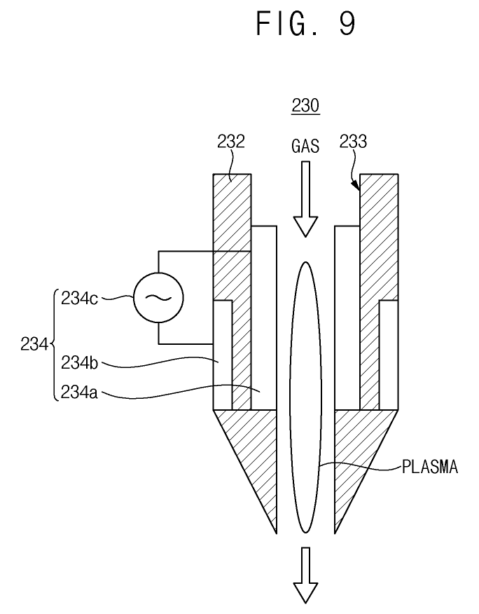

FIG. 7 is a cross-sectional view illustrating a fine polishing apparatus in accordance with example embodiments. FIG. 8 is a plan view illustrating the fine polishing apparatus of FIG. 7. FIG. 9 is a cross-sectional view illustrating a gas spray nozzle of the fine polishing apparatus of FIG. 7.

Referring to FIGS. 7 and 9, a fine polishing apparatus 200 may be provided in the fine polishing chamber 74 of FIG. 2 and may perform a fine polishing process using plasma gas without a polishing pad or abrasive.

In example embodiments, the fine polishing apparatus 200 may include a second substrate stage 210 configured to support a wafer W, a moving block 226 installed to be unidirectionally movable above the second substrate stage 210, a fluid injection nozzle 230 mounted on the moving block 226 and configured to inject a fluid including plasma gas or a reaction gas onto a surface of the wafer, and at least one thickness measurement sensor 240 mounted on the moving block 226 and configured to measure a thickness of a target layer on the surface of the wafer.

As illustrated in FIGS. 7 and 8, the second substrate stage 210 may be supported by a rotation shaft 214 and may rotate the wafer W at a desired rotation speed. When the second substrate stage 210 rotates, the wafer W may be adsorbed and fixedly supported on the second substrate stage 210.

The second substrate stage 210 may include a plurality of adsorption portions L1, L2, L3, L4 sequentially arranged in a radial direction from a center thereof, and temperature controllers 216a, 216b, 216c, 216d configured to control the temperature of each of the plurality of adsorption portions.

For example, suction holes may be formed in upper surfaces of the plurality of adsorption portions L1, L2, L3, L4. The wafer W may be vacuum-absorbed by the suction holes formed in an upper surface of the second substrate stage 210. The suction holes of the first to fourth adsorption portions L1, L2, L3, L4 may be individually connected to a vacuum pump (not illustrated) through pipes. Vacuum pressure may be provided to the suction holes individually or in groups. In this embodiment, the four adsorption portions may be provided, but it is not limited thereto, and the second substrate stage may have a plurality of adsorption portions, such as three, five, six, etc. Alternatively, the wafer may be adsorbed using an electrostatic force, such as an electrostatic chuck.

The temperature controllers 216a, 216b, 216c, 216d may be provided in the first to fourth adsorption portions L1, L2, L3, L4 to control the temperature of each of the adsorption portions. For example, the temperature controllers 216a, 216b, 216c, 216d may include heating elements such as a heating element or a resistance heating wire. In addition, the temperature controllers 216a, 216b, 216c, 216d may include refrigerant circulation lines for circulating refrigerant. The temperature controllers 216a, 216b, 216c, 216d may be independently controlled to perform local heating or cooling treatment on the wafer.

In example embodiments, the fine polishing apparatus 200 may further include a pair of first and second gantry support blocks 222a, 222b extending in a fourth direction (Y direction) from both sides of the second substrate stage 210, and a gantry 224 supported by the first and second gantry support blocks 222a, 222b and extending in a third direction (X direction). The pair of first and second gantry support blocks 222a, 222b may extend by a predetermined height in a vertical direction (Z direction) from a bottom surface of the polishing chamber 74, respectively. The gantry 224 may be installed to be reciprocally movable along the extension direction (Y direction) of the first and second gantry support blocks 222a, 222b along guides installed on the first and second gantry support blocks 222a, 222b. The moving block 226 may be installed to be reciprocally movable along the extension direction (X direction) of the gantry 224 along a guide installed on a front surface of the gantry 224. Accordingly, the moving block 226 may be movable in the third direction (X direction) and/or the fourth direction (Y direction) above the second substrate stage.

As illustrated in FIG. 9, the fluid injection nozzle 230 may include a main body 232 having a flow path 233 therein. Gas may be supplied to the fluid injection nozzle 230 through a supply portion of the flow path 233. In addition, a fluid including a polishing liquid, water, etc. may be introduced together into the flow path 233. The fluid injection nozzle 230 may include a plasma generator 234 configured to generate plasma within the gas within the fluid. The plasma generator 234 may include a first electrode 234a, a second electrode 234b, and a power source 234c.

The first electrode 234a may be provided on an inner surface of the flow path 233 and may come into contact with the fluid flowing within the flow path 233. The second electrode 234b may be provided within the main body 232 so as not to come into contact with the fluid flowing within the flow path 233. The power source 234c may apply a predetermined voltage between the first electrode 234a and the second electrode 234b. The first electrode 234a and the second electrode 234b may be covered by an insulating material (for example, a ceramic material).

The power source 234c may apply a predetermined voltage (for example, a high voltage of 1 to 20 kV) between the first electrode 234a and the second electrode 234b to generate plasma inside the gas in the flow path 233. That is, plasma micro-nano bubbles may be generated. Depending on the type of the gas, various radical species such as OH radicals may be generated, so that the gas is chemically activated and causes an oxidation action, an etching action, etc., to thereby perform a polishing process.

In example embodiments, the thickness measurement sensor 240 may be provided adjacent to the fluid injection nozzle 230 on the moving block 226. The thickness measurement sensor 240 may irradiate light onto a wafer surface and detect a reflected light to measure a change in distance from the wafer surface. In addition, the thickness measurement sensor 240 may detect polarization to measure a thickness of a target layer on the wafer.

In example embodiments, a position requiring fine polishing may be detected by the thickness measurement sensor 240, and the fluid injection nozzle 230 may inject a fluid including plasma gas or a reaction gas to the detected position to perform a fine polishing process. The fine polishing apparatus 200 may perform a fine polishing process using plasma gas without a polishing pad or abrasive.

In this embodiment, the fine polishing apparatus 200 includes the fluid injection nozzle 230 for performing a polishing process by injecting a fluid including plasma gas, but is not limited thereto. For example, the fluid injection nozzle may perform a fine polishing process by injecting a fluid including a reaction gas capable of removing a portion of a target layer.

Hereinafter, the cleaning chambers of the cleaning unit will be described in detail.

Referring again to FIGS. 1 to 4, each of the cleaning units CU of the cleaning unit block CUB may include cleaning chambers 80 that are stacked in multiple stages in the vertical direction (Z direction). The cleaning chambers 80 may remove contaminants such as organic substances, abrasives, and slurries remaining on the wafer surface on which the rough grinding process and the fine grinding process have been performed by the polishing units PU of the polishing unit block PUB. The cleaning chambers 80 may include a first cleaning chamber 82, a second cleaning chamber 84, a buffing chamber 88, and a drying chamber 86.

In example embodiments, the first cleaning chamber 82 may include a first substrate cleaning apparatus that scrubs and cleans the substrate by rubbing the substrate and contacting the substrate with a brush on both surfaces of the substrate. The first substrate cleaning apparatus may include a pair of brushes 320 configured to slidably contact and clean both surfaces of the wafer, and a plurality of spray nozzles 330 configured to spray a cleaning solution onto both surfaces of the wafer. Although not illustrated in the figures, the wafer may be provided with a plurality of rollers for holding and rotating the wafer in a horizontal direction. A roller driving mechanism, such as a motor, may be connected to at least one of the rollers. For example, a drive shaft of the motor may be connected to the roller through a power transmission mechanism, such as a gear or a pulley, to rotate the roller. As the roller rotates by the roller driving mechanism, the wafer may rotate while being held by the rollers.

The pair of brushes 320 may be installed on both surfaces of the wafer supported on the rollers. A plurality of cleaning protrusions may be formed on an outer surface of the brush 320. As the brush rotates around its own rotational axis, the cleaning protrusions may slide and contact one surface of the wafer to clean the wafer. The brush may include a soft polymer compound such as a sponge. Examples of the polymer compound may include PVA (Polyvinyl Alcohol), PFA (Paraformaldehyde), etc.

The spray nozzles 330 may spray a cleaning solution on the surface of the wafer scrubbed by the pair of brushes 320. For example, the cleaning solution may include a cleaning fluid such as diluted NH₄OH or HF.

In example embodiments, the second cleaning chamber 84 may include a second substrate cleaning apparatus that sprays a cleaning solution on one surface of the substrate to clean the substrate. The second substrate cleaning apparatus may include a substrate stage configured to support and rotate the substrate, and a cleaning nozzle 340 configured to supply a rinse liquid to the substrate to clean the substrate. In addition, the second substrate cleaning apparatus may include a cup structure that is provided to surround an outer periphery of the substrate and collect the cleaning liquid flying from the rotating substrate.

In example embodiments, the drying chamber 86 may include a spin drying apparatus that removes liquid droplets attached to the substrate by rotating the substrate at a high speed after the substrate is cleaned. The spin drying apparatus may include a substrate stage configured to hold and support the substrate horizontally and rotate it. In addition, the spin drying apparatus may further include a liquid splash prevention cup that generally surrounds an outer periphery of the substrate held and supported by the substrate stage in order to prevent the liquid droplets removed by centrifugal force from scattering from the rotating substrate.

In example embodiments, the buffing chamber 88 may include a buffing apparatus that removes and cleans attachments on the substrate while contacting and relatively moving a buffing pad 350 to the substrate between the polishing process and the cleaning process of the substrate. The buffing apparatus may include guide rollers configured to contact and rotate the wafer, a pair of buffing pads 350 configured to contact and clean both surfaces of the wafer, and driving units configured to rotate and move the buffing pad. It will be understood that the arrangement, type, and number of the cleaning units are illustrative and that example embodiments are not limited thereto.

Hereinafter, a method of processing a wafer using the substrate polishing system will be described.

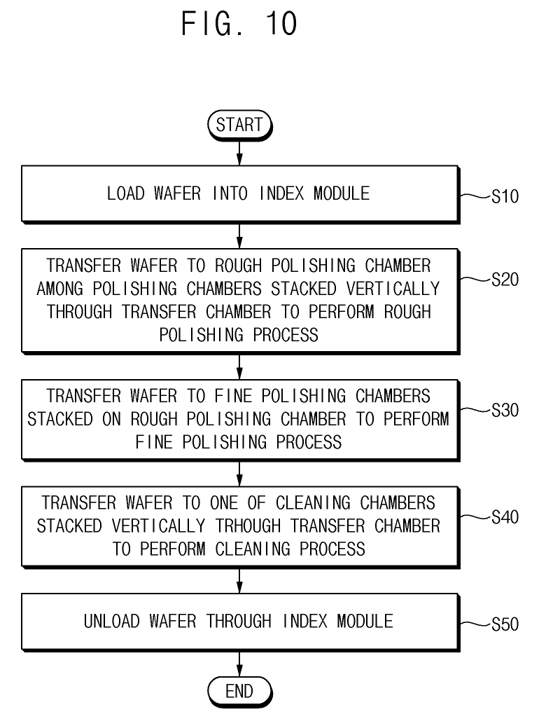

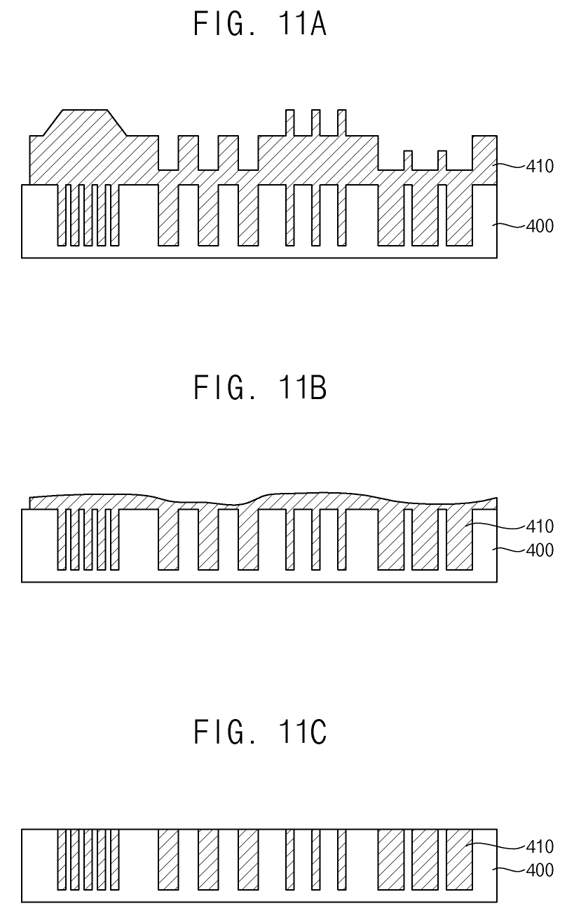

FIG. 10 is a flow chart illustrating a substrate processing method in accordance with example embodiments. FIGS. 11A, 11B, and 11C are cross-sectional views illustrating a target layer on a substrate on which the substrate processing method of FIG. 10 is performed.

Referring to FIGS. 1 to 11C, wafers may be provided on a load port 20 of an index module IM (S10), the wafers may be transferred to a rough polishing chamber 72 of a polishing unit block PUB through a transfer chamber 50 (S20).

In example embodiments, a wafer carrier C containing the wafers on which a polishing target layer is formed may be loaded into the index module IM. An indexer robot 40 may transfer the wafer from the wafer carrier C to a transfer robot 60 arranged in one side of the index module IM, and the transfer robot 60 may transfer the wafer to the rough polishing chamber 72 of the polishing unit block PUB in a first side of a transfer chamber 50.

The transfer robot 60 may move along a transfer rail in a first direction (X direction) to one polishing unit selected from a plurality of polishing units PU, and a robot hand 66 may load the wafer into a rough polishing apparatus 100 of the rough polishing chamber 72 of the selected polishing unit along a vertical guide 75.

As illustrated in FIG. 11A, in example embodiments, a target layer to be etched may be a silicon oxide layer 410 formed on a substrate 400. For example, the substrate 400 may include a semiconductor substrate, such as a silicon substrate, a germanium substrate, a silicon-germanium substrate, a silicon-on-insulator (SOI) substrate, a germanium-on-insulator (GOI) substrate, etc. A pattern structure such as a trench may be formed in an upper surface of the substrate 400, and the silicon oxide layer 410 may be provided to fill the trench on the upper surface of the substrate 400.

Then, a rough polishing process may be performed on the wafer within the rough polishing chamber 72.

The rough polishing apparatus 100 of FIG. 5 may perform a rough polishing process by spraying high-speed droplets while rotating the wafer. Temperature controllers 116a, 116b, 116c, 116 may be provided in first to fourth adsorption portion R1, R2, R3, R4 respectively to control the temperature of each of the adsorption portions.

The temperature controllers 116a, 116b, 116c, 116d may be independently controlled to perform local heating or cooling treatment on the wafer. Thickness measurement sensors 130 may irradiate light onto the wafer surface and detect a reflected light to measure a change in distance from the wafer surface. In addition, the thickness measurement sensors 130 may measure a thickness of the target layer on the wafer by detecting polarization.

As illustrated in FIG. 11B, the rough polishing process may be performed during a first process time to partially remove an upper portion of the silicon oxide layer 410. For example, the first process time may be 30 sec to 80 sec.

In example embodiments, the rough polishing process may be performed by spraying high-speed droplets without a polishing pad or abrasive, so that maintenance of consumables is not required, there are no defects due to the abrasive, and a conditioner may be eliminated. In addition, by directly measuring the wafer surface, thickness measurement resolution may be improved to a level of 0.1 nm. Further, the polishing efficiency may be improved by reducing the temperature deviation through local heating and cooling treatment of the wafer through the temperature controllers.

Then, after performing the rough polishing process, the wafer may be transferred to a fine polishing chamber 74 of the polishing unit block PUB through the transfer chamber 50 (S30).

In example embodiments, the transfer robot 60 in the transfer chamber 50 may transfer the wafer from the rough polishing chamber 72 of the polishing unit block PUB to the fine polishing chamber 74. The fine polishing chamber 74 may be stacked on the rough polishing chamber 72 in a vertical direction (Z direction). The transfer robot 60 may unload the wafer on which the rough grinding process has been performed from the rough polishing chamber 72 of the selected polishing unit, and the robot hand 66 may load the wafer into a fine polishing apparatus 200 of the fine polishing chamber 74 stacked on the rough polishing chamber 72 along the vertical guide 75.

Then, a fine polishing process may be performed on the wafer in the polishing chamber 74.

The fine polishing apparatus 200 of FIG. 7 may measure a thickness of the target layer on the wafer surface, detect a position requiring fine polishing, and perform the polishing process by injecting a fluid including plasma gas or a reaction gas onto the detected position. A fluid injection nozzle 230 may perform the fine polishing process by injecting a fluid including plasma gas or a reaction gas onto the surface of the wafer.

Temperature controllers 216a, 216b, 216c, 216d may be provided in first to fourth adsorption portions L1, L2, L3, L4 to control temperature of each of adsorption portions of a second substrate stage 210. The temperature controllers 216a, 216b, 216c, 216d may be independently controlled to perform local heating or cooling treatment on the wafer. Thickness measurement sensors 240 may measure a change in distance from the wafer surface by irradiating light onto the wafer surface and detecting a reflected light. In addition, the thickness measurement sensors 240 may measure a thickness of the target layer on the wafer by detecting polarization.

As illustrated in FIG. 11C, a position requiring fine polishing on the surface of the silicon oxide layer 410 may be detected, and a fluid including plasma gas or a reaction gas may be sprayed onto the detected position to perform a fine polishing process. Accordingly, the polishing precision may be improved. The fine polishing process may be performed during a second process time. The second process time may be shorter than the first process time. For example, the second process time may be 10 sec to 60 sec.

Then, after performing the fine polishing process, the wafer may be transferred to one of cleaning chambers 80 of the cleaning unit block CUB through the transfer chamber 50 (S40).

In example embodiments, the transfer robot 60 in the transfer chamber 50 can transfer the wafer from the polishing chamber 74 of the polishing unit block PUB to one of the cleaning chambers 80 of the cleaning unit block CUB.

For example, the transfer robot 60 may unload the wafer from the fine polishing chamber 74, move along the transfer rail in the first direction (X direction) to one cleaning unit CU selected from among a plurality of cleaning units, and the robot hand 66 may load the wafer into a buffing treatment apparatus of a buffing chamber 88 of the selected cleaning unit along the vertical guide 75.

The buffing chamber 88 may remove and clean attachments on the substrate by contacting the substrate with a buffing pad 350 and causing relative movement between the polishing treatment and the cleaning treatment of the substrate.

Then, the transfer robot 60 may sequentially transfer the wafer on which the buffing process has been completed, through the first cleaning chamber 82, the second cleaning chamber 84, and the drying chamber 86 according to the cleaning recipe. Then, the transfer robot 60 may sequentially transfer the wafer to the index chamber 30.

Then, the wafer on which the cleaning process has been performed may be unloaded through the index module IM (S50).

The above substrate polishing apparatus may be used to manufacture a semiconductor package including semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A substrate polishing system, comprising:
an index module having a load port configured to support wafer carriers, each of the wafer carriers configured to support a plurality of wafers, and an index chamber configured to transfer wafers to and from the wafer carriers;
a transfer chamber extending in a first direction from a first side of the index module; and
a plurality of polishing units sequentially arranged in the first direction along a first side of the transfer chamber,
wherein each polishing unit of the plurality of polishing units includes vertically stacked polishing chambers stacked in multiple stages, and the vertically stacked polishing chambers include a rough polishing chamber and a fine polishing chamber.

2. The substrate polishing system of claim 1, wherein the fine polishing chamber is stacked on the rough polishing chamber.

3. The substrate polishing system of claim 2, wherein the fine polishing chamber is one of a plurality of fine polishing chambers and the rough polishing chamber is one of a plurality of rough polishing chambers and the quantity of the plurality of rough polishing chambers of the vertically stacked polishing chambers is greater than the quantity of the plurality of fine polishing chambers of the vertically stacked polishing chambers.

4. The substrate polishing system of claim 1, wherein the rough polishing chamber includes:
a first substrate stage configured to support a wafer;
a fluid injection portion above the first substrate stage and having a fluid discharge head configured to inject a high-pressure fluid onto a surface of the wafer; and
a thickness measurement sensor above the first substrate stage and configured to measure a thickness of a target layer on the surface of the wafer.

5. The substrate polishing system of claim 4, wherein the fluid discharge head has injection holes that are spaced apart from each other along a second direction and are configured to inject droplets into the rough polishing chamber through the injection holes.

6. The substrate polishing system of claim 4, wherein the first substrate stage includes:
a plurality of adsorption portions sequentially arranged in a radial direction from a center of the first substrate stage, and
temperature controllers configured to control the temperature of each of the plurality of adsorption portions.

7. The substrate polishing system of claim 1, wherein the fine polishing chamber includes:
a second substrate stage configured to support a wafer;
a moving block unidirectionally movable above the second substrate stage;
a fluid injection nozzle on the moving block and configured to inject a fluid including a plasma gas or a reaction gas onto a surface of the wafer; and
a thickness measurement sensor on the moving block and configured to measure a thickness of a target layer on the surface of the wafer.

8. The substrate polishing system of claim 7, further comprising:
a pair of first and second gantry support blocks extending in a third direction from opposing sides of the second substrate stage; and
a gantry supported by the first and second gantry support blocks and extending in a fourth direction perpendicular to the third direction, wherein the moving block is mounted on the gantry.

9. The substrate polishing system of claim 7, wherein the second substrate stage includes:
a plurality of adsorption portions sequentially arranged in a radial direction from a center of the second substrate stage; and
temperature controllers configured to control temperature of each of the plurality of adsorption portions.

10. The substrate polishing system of claim 1, further comprising:
a plurality of cleaning units sequentially arranged in the first direction at a second side of the transfer chamber opposite to the first side,
wherein each of the plurality of cleaning units includes cleaning chambers vertically stacked in multiple stages.

11. A substrate polishing system, comprising:
an index module having a load port configured to support wafer carriers, each of the wafer carriers configured to support a plurality of wafers, and an index chamber configured to load and unload the plurality of wafers;
a transfer chamber extending in a first direction from a first side of the index module and having a transfer robot that is movable along the first direction;
a plurality of polishing units sequentially arranged in the first direction along a first side of the transfer chamber; and
a plurality of cleaning units sequentially arranged in the first direction along a second side of the transfer chamber opposite to the first side,
wherein each polishing unit of the plurality of polishing units includes vertically stacked polishing chambers stacked in multiple stages, and the vertically stacked polishing chambers include a rough polishing chamber and a fine polishing chamber, and
wherein each cleaning unit of the plurality of cleaning units includes vertically stacked cleaning chambers stacked in multiple stages.

12. The substrate polishing system of claim 11, wherein the fine polishing chamber is stacked on the rough polishing chamber.

13. The substrate polishing system of claim 12, wherein the fine polishing chamber is one of a plurality of fine polishing chambers and the rough polishing chamber is one of a plurality of rough polishing chambers and the quantity of the plurality of rough polishing chambers of the vertically stacked polishing chambers is greater than the quantity of the plurality of fine polishing chambers of the vertically stacked polishing chambers.

14. The substrate polishing system of claim 11, wherein the rough polishing chamber includes:
a first substrate stage configured to support a wafer;
a fluid injection portion above the first substrate stage and having a fluid discharge head configured to inject a high-pressure fluid onto a surface of the wafer; and
a thickness measurement sensor above the first substrate stage and configured to measure a thickness of a target layer on the surface of the wafer.

15. The substrate polishing system of claim 14, wherein the fluid discharge head has injection holes that are spaced apart from each other along a second direction and is configured to inject droplets into the rough polishing chamber through the injection holes.

16. The substrate polishing system of claim 14, wherein the first substrate stage includes:
a plurality of adsorption portions sequentially arranged in a radial direction from a center of the first substrate stage; and
temperature controllers configured to control the temperature of each of the plurality of adsorption portions.

17. The substrate polishing system of claim 11, wherein the fine polishing chamber includes:
a second substrate stage configured to support a wafer;
a moving block unidirectionally movable above the second substrate stage;
a fluid injection nozzle on the moving block and configured to inject a fluid including a plasma gas or a reaction gas onto a surface of the wafer; and
a thickness measurement sensor on the moving block and configured to measure a thickness of a target layer on the surface of the wafer.

18. The substrate polishing system of claim 17, further comprising:
a pair of first and second gantry support blocks extending in a third direction from opposing sides of the second substrate stage; and
a gantry supported by the first and second gantry support blocks and extending in a fourth direction perpendicular to the first direction, wherein the moving block is mounted on the gantry to be movable.

19. The substrate polishing system of claim 11, wherein the vertically stacked cleaning chambers include at least one of a first cleaning chamber having a brush, a second cleaning chamber having a cleaning nozzle, a buffing chamber, and a drying chamber.

20. A substrate polishing system, comprising:
a transfer chamber extending in a first direction, the transfer chamber having a first end configured to receive wafers;
a plurality of polishing units arranged sequentially in the first direction along a first side of the transfer chamber;
a plurality of cleaning units arranged sequentially in the first direction along a second side of the transfer chamber opposite to the first side; and
a transfer robot within the transfer chamber movable in the first direction and along a vertical transfer path, the transfer robot configured to transfer the wafers between the first end of the transfer chamber, the plurality of polishing units, and the plurality of cleaning units,
wherein each polishing unit of the plurality of polishing units includes vertically stacked polishing chambers that are stacked in multiple stages, and the vertically stacked polishing chambers include a rough polishing chamber and a fine polishing chamber that is stacked on the rough polishing chamber, and
wherein each cleaning unit of the plurality of cleaning units includes vertically stacked cleaning chambers that are stacked in multiple stages.
